(19) United States
(12) Patent Application Publication
(10) Pub. No.: US 2001/0046727 A1
(43) Pub. Date: Nov. 29, 2001

(54) METHOD FOR FABRICATING A GATE CONDUCTIVE STRUCTURE

(76) Inventors: CHIH-HUNG LIN, HSINCHU (TW); CLAYMENS LEE, FENGSHAN CITY (TW)

Correspondence Address: J C PATENTS INC, 4 Venture, Suite 250, IRVINE, CA, 92618, US

(21) Appl. No.: 09/328,850

(22) Filed: Jun. 9, 1999

(51) Int. Cl. H01L 21/8232

(52) U.S. Cl. 438/142

(57) ABSTRACT

This invention provides a method for fabricating a gate conductive structure. A semiconductor substrate having a gate oxide layer thereon is provided. A conductive layer is formed on the gate oxide layer. Then, a mask layer is formed on the conductive layer. Thereafter, the mask layer and the conductive layer are patterned to form a gate mask layer and a gate conductive layer. Next, a first spacer is formed on sidewalls on the gate conductive layer and the gate mask layer, wherein the spacer is taller than the gate conductive layer. After that, the gate mask layer is removed. Then, a second spacer is formed on the gate conductive layer and adjacent to the first spacer. The second spacer is made of polysilicon so that the second spacer is conductive. Finally, a silicide layer is then formed on the surface of the second spacer and the gate conductive layer.

### BACKGROUND OF THE INVENTION

1. Field of Invention

This invention relates to a method for fabricating a gate conductive structure, and more particularly, to a method for reducing the resistance of the gate conductive structure.

2. Description of Related Art

As integration of a semiconductor device increases, line width and pattern dimension of the semiconductor device then accordingly decrease. The reduced line width may result in higher resistance for a wire line in the semiconductor device or a polysilicon gate of a metal-oxide semiconductor (MOS) transistor. A conventional method used to solve this problem includes forming one metal layer on a silicon-contained surface, and performing a rapid thermal process (RTP) to convert the metal layer into a silicide layer on the polysilicon gate. Because the silicide layer has better conductivity, resistance of the polysilicon gate is reduced.

Typically, the silicide layer is formed by a self-aligned silicide process with a self-aligned property, which layer is also called a Salicide layer.

FIGS. 1A through 1C are schematic, cross-sectional views showing the steps according to a conventional method of forming self-aligned silicide layers over the terminals of a MOS device. First, as shown in FIG. 1A, a semiconductor substrate 100 having an insulating structure 102 therein is provided. A gate structure 103 comprising a gate oxide layer 104 and a polysilicon layer 106 is formed on the substrate 100. A source/drain region 108 is formed in the substrate 100 adjacent to the gate structure 103. In addition, there are spacers 105 on the sidewalls of the gate structure 103.

Next, as shown in FIG. 1B, a metal layer 110 is formed over the substrate 100 including the gate structure 103. Thereafter, a rapid thermal process (RTP) is carried out so that part of the titanium in the titanium layer 110 reacts with silicon in the polysilicon layer 106 and the source/drain 108. Therefore, a titanium silicide layer 112 is formed over the upper surface of the gate polysilicon layer 106 and the source/drain 108.

In the subsequent step, the unreacted titanium in the titanium layer 110 resulting from the reaction is removed. Finally, as shown in FIG. 1C, the gate structure with a silicide layer is complete.

However, as the dimension of the gate becomes smaller, the stress between the gate and the metal silicide layer is increased. In addition, the nucleation site of the metal silicide layer is decreased. There may be too few nucleation sites on the original surface for formation of a high quality metal silicide layer, thereby leading to an increase in sheet resistant that may frequently affect the operation of the transistor gate in ways such as RC Delay.

### SUMMARY OF THE INVENTION

The invention provides a method for fabricating a gate conductive structure. This method increases the area of the silicide layer formed on the gate conductive layer, such that the resistance of the gate conductive layer is reduced. Additionally, the channel length of the device is not changed.

To achieve this and other advantages and in accordance with the purpose of the invention, this invention provides a method for fabricating a gate conductive structure. A semiconductor substrate having a gate oxide layer thereon is provided. A conductive layer is formed on the gate oxide layer. Then, a mask layer is formed on the conductive layer. Thereafter, the mask layer and the conductive layer are patterned to form a gate mask layer and a gate conductive layer. Next, a first spacer is formed on sidewalls of the gate conductive layer and the gate mask layer, wherein the spacer is taller than the gate conductive layer. After that, the gate mask layer is removed. Then, a second spacer is formed on the gate conductive layer and adjacent to the first spacer. The second spacer is made of polysilicon so that the second spacer is conductive. Finally, a silicide layer is then formed on the surface of the second spacer and the gate conductive layer.

As embodied and broadly described herein, the invention provides a method of fabricating a gate conductive structure, wherein the gate conductive layer is made of polysilicon. In addition, the process for forming the second spacer comprises the following steps. A polysilicon layer is formed to cover the gate conductive layer and the first spacer. Next, anisotropic etching is carried out to etch back the polysilicon and the second spacer is formed.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1A through FIG. 1C are schematic, cross-sectional views showing the steps according to a conventional method of forming self-aligned silicide layers over the terminals of a MOS device.; and

FIG. 2A through FIG. 2E are schematic, cross-sectional views showing the steps according to a conventional method of forming self-aligned silicide layers over the terminals of a MOS device according to one preferred embodiment of this invention.

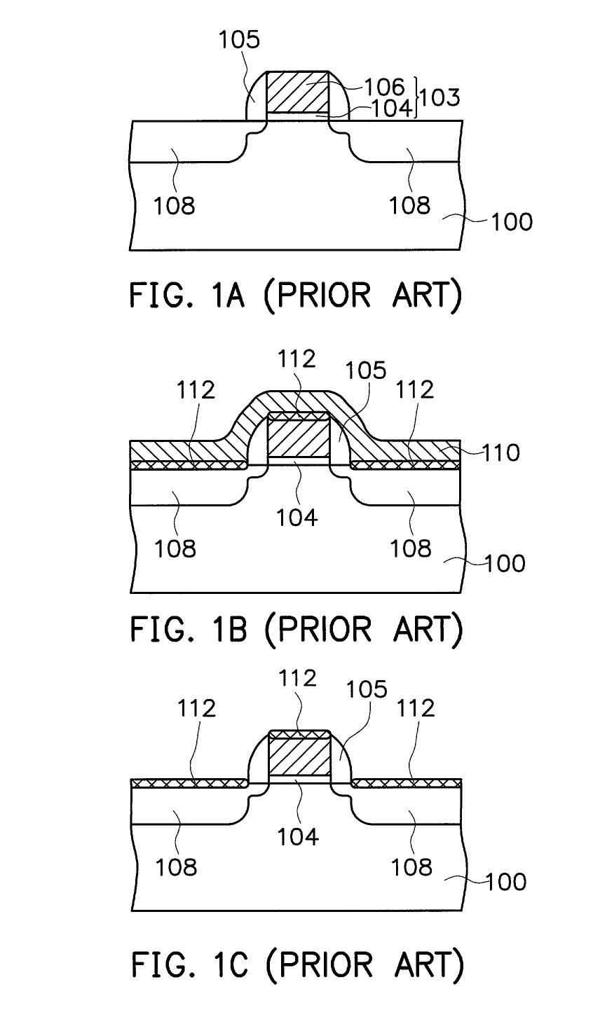

### DESCRIPTION OF THE PREFERRED EMBODIMENTS

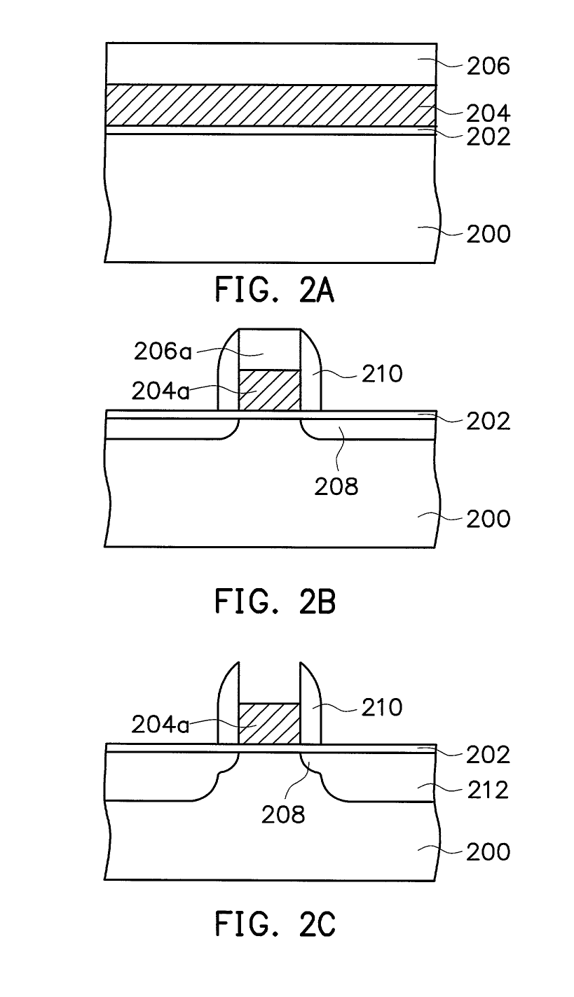

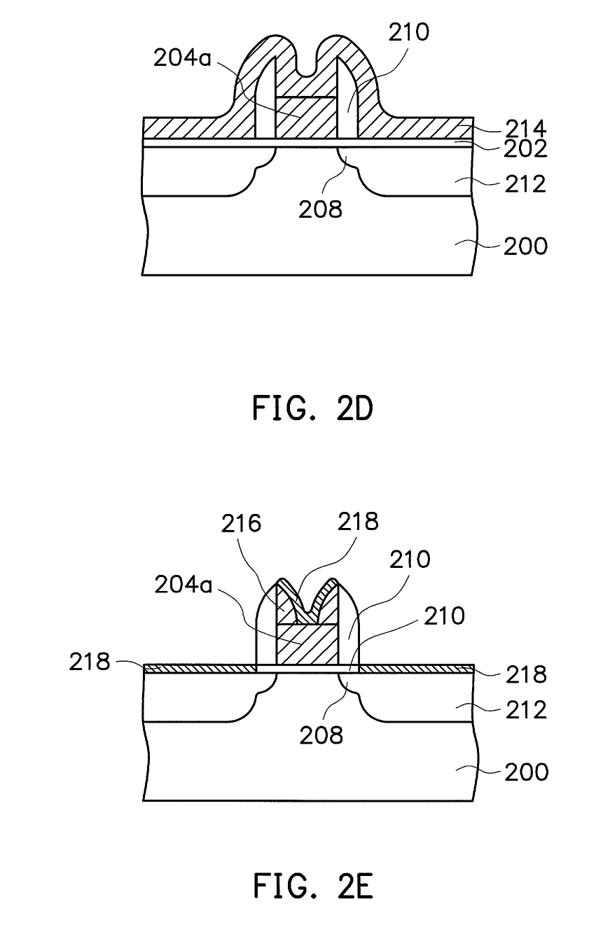

As shown in FIG. 2A, a semiconductor substrate 200 is provided, and then a gate oxide layer 202 is formed by, for example, thermal oxidation on the substrate 200. A conductive layer 204 is formed, for example, by chemical vapor deposition (CVD) on the gate oxide layer 202. The conductive layer 204 is made of, for example, polysilicon. A mask layer 206 is formed, for example, by chemical vapor deposition on the conductive layer 204. The mask layer 206 is formed of, for example, silicon nitride.

Next, referring to FIG. 2B, the gate conductive layer 204a and the gate mask layer 206a are defined, for example, by photolithography and dry etching to pattern the polysilicon layer 204 and the mask layer 206. A spacer 210 is formed on the sidewalls of the gate conductive layer 204a and the gate mask layer 206a. Before the spacer 210 formed, an ion implantation is carried out to form a lightly doped region 208 in the substrate 200. The spacer 210 is made of, for example, silicon oxide. It is should be noted that the spacer 210 is taller than the conductive layer 204a.

Referring to FIG. 2C, another ion implantation process is performed by using the gate mask layer 206a and the spacer 210 as a mask so that a source/drain region 212 is formed in the substrate 200. After that, the gate mask layer 206a is removed by using, for example, wet etching.

Referring to FIG. 2D, a polysilicon layer 214 is formed over the substrate 200 to cover the gate conductive layer 204a and the spacer 210. The polysilicon layer 214 is formed by using, for example, chemical vapor deposition.

Next, referring to FIG. 2E, the polysilicon layer 214 is etching back to form a polysilicon spacer 216, wherein the polysilicon spacer 216 is located on the gate conductive layer 204a and is adjacent to the spacer 210. Typically, the etching back process of the polysilicon layer 214 is an anisotropic etching process such as dry etching. Then, a portion of the gate oxide layer 202 is removed by using the gate conductive layer 204a and the spacer 210 as an etching mask, so that the surface of the source/drain region 212 is exposed. A silicide layer 218 is formed on the surface of the spacer 216, the gate conductive layer 204a and the source/drain region 212. Typically, the silicide layer 218 is made of, for example, tungsten silicide and titanium silicide. Preferably, the silicide layer 218 is made of titanium silicide. The silicide layer 218 is formed by using a conventional self-aligned silicide process. For example, a metal layer is first formed on the surface of the spacer 216, the gate conductive layer 204a and the source/drain region 212 by sputtering. Then a rapid thermal process is carried so that the metal layer partially reacts with the silicon at the surface of the spacer 216, the gate conductive layer 204a and the source/drain region 212. Finally, the residual metal is removed by a wet etching process and the gate conductive structure according to this invention is completed.

This invention has many advantages. The existence of the polysilicon spacer on the gate conductive layer increases the area of the silicide formed on the gate conductive layer. Therefore the resistance of the gate is reduced to prevent the RC delay of the gate structure. Accordingly, the performance of the device is improved.

In this invention, the area of the silicide formed on the gate conductive layer is increased without raising the gate width.

In this invention, the area of the silicide formed on the gate conductive layer is increased without making changes in the channel length.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for fabricating a gate conductive structure on a semiconductor substrate, comprising:
forming a gate oxide layer over the semiconductor substrate;
forming a conductive layer over the gate oxide layer;
forming a mask layer over the conductive layer;
patterning the conductive layer and the mask layer to form a gate conductive layer and a gate mask layer, wherein the gate conductive layer and the gate mask layer have sidewalls;
forming a first spacer on the sidewalls of the gate conductive layer and the gate mask layer;
removing the gate mask layer; and
forming a second spacer on the gate conductive layer and adjacent to the first spacer.

2. The method of claim 1, wherein the first spacer is taller than the gate conductive layer.

3. The method of claim 1, wherein the second spacer comprises polysilicon.

4. The method of claim 3, wherein the formation of the second spacer comprises the following steps:
forming a polysilicon layer over the substrate to cover the gate conductive layer and the first spacer; and
anisotropically etching back the polysilicon layer to form the second spacer.

5. The method of claim 1, wherein the conductive layer comprises polysilicon.

6. The method of claim 1, wherein the mask layer comprises silicon nitride.

7. The method of claim 1, further comprising forming a silicide layer on the surface of the gate conductive layer a the second spacer layer.

8. The method of claim 7, wherein the silicide layer is selected from the group consisting of tungsten silicide and titanium silicide.

9. A method for fabricating a gate conductive structure on a semiconductor substrate, comprising:
forming a gate oxide layer over the semiconductor substrate;
forming a first polysilicon layer over the gate oxide layer;
forming a mask layer over the first polysilicon layer;
defining a gate conductive layer and a gate mask layer by patterning the first polysilicon layer and the mask layer, wherein the gate conductive layer and the gate mask layer have sidewalls;
forming a first spacer on the sidewalls of the gate conductive layer and the gate mask layer;
removing the gate mask layer;
forming a second polysilicon layer over the substrate to wholly cover the gate conductive layer and the first spacer;
anisotropically etching back the second polysilicon layer to form a second spacer on the gate conductive layer and adjacent to the first spacer; and
forming a silicide layer on the surface of the gate conductive layer and the second spacer layer.

10. The method of claim 9, wherein the first spacer is taller than the gate conductive layer.

11. The method of claim 9, wherein the mask layer comprises silicon nitride.

12. The method of claim 9, wherein the silicide layer is selected from the group consisting of tungsten silicide and titanium silicide.

13. A method for decreasing the resistance of a gate structure on a semiconductor substrate, wherein the substrate has a gate oxide layer thereon, the method comprising:
forming a first polysilicon layer over the gate oxide layer;
forming a mask layer over the first polysilicon layer;
patterning the first polysilicon layer and the mask layer to form a gate conductive layer and a gate mask layer, wherein the gate conductive layer and the gate mask layer have sidewalls;
forming a first spacer on the sidewalls of the gate conductive layer and the gate mask layer;
removing the gate mask layer;
forming a second polysilicon layer over the substrate to cover the gate conductive layer and the first spacer;
anisotropically etching back the second polysilicon layer to form a second spacer on the gate conductive layer and adjacent to the first spacer; and
forming a silicide layer on the surface of the gate conductive layer and the second spacer layer.

14. The method of claim 13, wherein the first spacer is taller than the gate conductive layer.

15. The method of claim 13, wherein the mask layer comprises silicon nitride.

16. The method of claim 13, wherein the silicide layer comprises titanium silicide.
